(19) United States
(12) Patent Application Publication
(10) Pub. No.: US 2005/0253287 A1
(43) Pub. Date: Nov. 17, 2005

(54) Dual-port SRAM cell structure

(75) Inventor: Jhon Jhy Liaw, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 10/844,214

(22) Filed: May 11, 2004

(51) Int. Cl. G11C 11/00

(52) U.S. Cl. 257/903

(57) ABSTRACT

A cell structure is disclosed for a dual port static random access memory (SRAM) cell. The SRAM cell occupies a substantially rectangular cell area. The cell structure comprises a first port having two bit signal lines, and a second port having two bit signal lines, wherein the two bit signal lines of each port are on two separate metal layers.

### BACKGROUND

The present invention generally relates to computer memories; and more particularly, to static random access memories (SRAMs). Still more particularly, the present invention relates to dual-port SRAM structures.

One type of basic storage memory is the CMOS static random access memory (SRAM). SRAM retains its memory state without refreshing, as long as power is supplied to the cells. In a typical SRAM, the memory state is stored as a voltage differential within a bistable cell constructed of two cross-coupled inverters. Data is written into, or read from, the cell through two pass gate transistors oppositely biased by a bit line and a bit bar line and controlled by a word line.

One variation of SRAM designs is a dual-port SRAM structure. This structure has speed advantages because it can simultaneously sustain two read operations. Typically, a dual-port SRAM structure includes two inverters. Each inverter is composed of a P-channel MOS transistor in series with an input/output (I/O) node and an N-channel MOS transistor. The node of each inverter is connected to the gates of both transistors of the other inverter. Two I/O transistors are individually connected from the first and second bit lines to the node of a first inverter. Two more I/O transistors are individually connected from a first and a second bit line bar (always biased oppositely from the corresponding bit line) to the node of a second inverter. In SRAM devices, large memory cell count, stable data retention, and speed are considerable concerns. The speed and stability are degraded by on-chip wiring capacitance and bit line cross-coupling noise.

As such, desirable in the art of memory devices are additional designs that provide reduced degradation and enhanced performance.

### SUMMARY

In view of the foregoing, a cell structure is disclosed for a dual port static random access memory (SRAM) cell. The SRAM cell occupies a substantially rectangular cell area. The cell structure comprises a first port having two bit signal lines, and a second port having two bit signal lines, wherein the two bit signal lines of each port are on two separate metal layers.

Various aspects and advantages will become apparent from the following detailed description, taken in conjunction with the accompanying drawings, illustrating the principles of the invention by way of embodiments.

### BRIEF DESCRIPTION OF THE DRAWINGS

FIG. 1 illustrates a circuit diagram for a standard dual-port SRAM.

FIG. 2 illustrates the first layer of an SRAM on a semiconductor chip in accordance with one embodiment of the present invention.

FIG. 3 illustrates a first layout pattern of the second and fourth metal layers of an SRAM chip in accordance with one embodiment of the present invention.

FIG. 4 illustrates a second layout pattern of the second and fourth metal layers of an SRAM chip in accordance with one embodiment of the present invention.

FIG. 5 illustrates a layout pattern of the third metal layer of an SRAM chip in accordance with one embodiment of the present invention.

### DESCRIPTION

As the demand for more complex integrated circuits, smaller transistors and structures, and faster, more reliable performance continues to grow, new approaches are needed. The close proximity of metal layer interconnections to the chip substrate and to each other must receive attention. The present invention changes the spatial relationships among the metal interconnection lines to reduce their capacitance relative to the chip substrate and to each other, and to introduce electronic shielding that reduces cross-talk and noise. The present invention provides an improved dual-port SRAM design, and the stable, high-speed memory cell operation is therefore achieved.

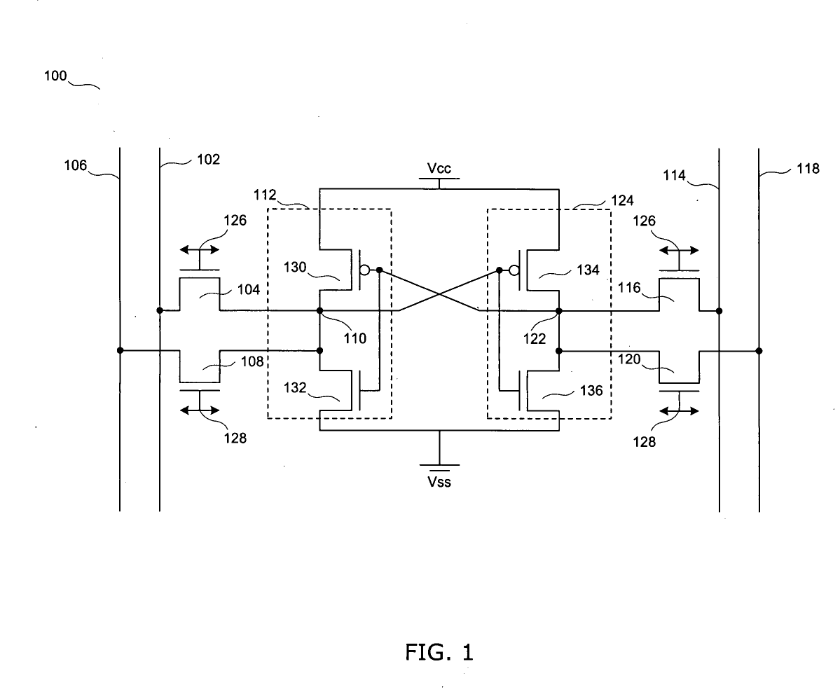

FIG. 1 illustrates a standard eight transistor dual-port SRAM 100 according to one embodiment of the present invention, which can be a modification of a standard, six-transistor, static random access memory (SRAM), with the addition of two extra pass gates. Both a port-1 bit line 102, through a pass gate 104, and a port-2 bit line 106, through a pass gate 108, are connected to a node 110. Both a port-1 bit line bar 114, through a pass gate 116, and a port-2 bit line bar 118, through a pass gate 120, are connected to a node 122. The bit line and bit line bar for any particular port are more generically referred to as bit signal lines. Node 110 connects to an inverter 124; and, similarly, node 122 connects to another inverter 112. A pass gate is a nMOS transistor with its drain connected to a bit line or to a bit line bar, its source connected to a node of an inverter, and its gate connected to a word line. Pass gates 104 and 116 are controlled by a port-1 word line 126. Pass gates 108 and 120 are controlled by a port-2 word line 128. The operating power supply VCC is connected to the source of a pMOS transistor 130 of the inverter 112. The drain of the transistor 130 is node 110. A second power supply line or the ground line VSS is connected to the source of a nMOS transistor 132 of the inverter 112. The drain of the transistor 132 is also node 110. Similarly, VCC is connected to the source of a pMOS transistor 134, whose drain is connected to node 122. VSS is connected to the source of a nMOS transistor 136 of the inverter 124. The drain of transistor 136 is connected to node 122. Node 110 is connected to the gate of transistor 134, and to the gate of transistor 136. Node 122 is connected to the gate of transistor 130, and to the gate of transistor 132.

As shown, the two inverters 112 and 124 are cross connected with node 110 of inverter 112, connected to the gates of inverter 124, and node 122, of inverter 124, connected to the gates of inverter 112. This cross-coupling locks inputted data in a stable storage. This stored data is available for non-destructive read. A dual-port SRAM can sustain only one write operation at a time, but it can sustain two simultaneous read operations without losing the stable memory data state. This increases overall speed.

The present invention achieves further speed increase by reducing the capacitance of metal wiring lines, and by reducing cross-talk between metal wiring lines on a memory chip.

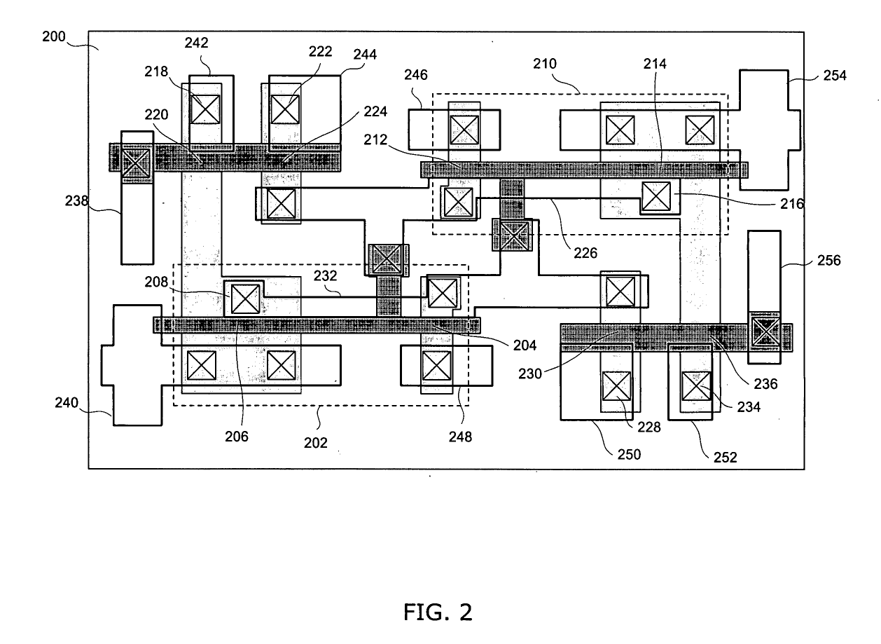

FIG. 2 illustrates a circuit layout 200 of an SRAM cell corresponding to the SRAM circuit, as shown in FIG. 1. As shown, the SRAM cell 200 occupies a substantially rectangular area, with a short side and a long side. For an inverter 202, VCC is connected to the source of a pMOS transistor 204. The drain of the transistor 204 is connected to the drain of a nMOS transistor 206, and a node 208. VSS is connected to the source of the transistor 206. In an inverter 210, VCC is connected to the source of a pMOS transistor 212. The drain of the transistor 212 is connected to the drain of a nMOS transistor 214, and a node 216. VSS is connected to the source of the transistor 214. As indicated by dashed box 202 and 210, the N well and P well, in the semiconductor substrate, are placed in the same orientation as the entire rectangular area occupied by the SRAM cell 200. That is, the short and long sides of the wells are parallel with the short and long sides of the cell area respectively. As it is understood in the art, circuits are manufactured by laying multiple layers of materials together and making appropriate connections. A port-1 bit line contact 218 is connected to the drain of a nMOS transistor 220. The source of the transistor 220 is connected to the node 208. A port-1 bit line bar contact 222 is connected to the drain of a nMOS transistor 224. The source of the transistor 224 is connected to the node 216 by a connector 226 of the first metal layer. A port-2 bit line contact 228 is connected to the drain of a NMOS transistor 230. The source of the transistor 230 is connected to the node 208 by a connector 232 of the first metal layer. A port-2 bit line bar contact 234 is connected to the drain of a nMOS transistor 236. The source of the transistor 236 is connected to the node 216.

Other first metal layer elements include a port-1 word line landing pad 238, a VSS node 240 and its contact structures such as the two vias shown thereon, a port-1 bit line contact 242, a port-1 bit line bar contact 244, a VCC node 246, a VCC node 248, a port-2 bit line contact 250, a port-2 bit line bar contact 252, a VSS node 254, and a port-2 word line landing pad 256 and its contact structure or via.

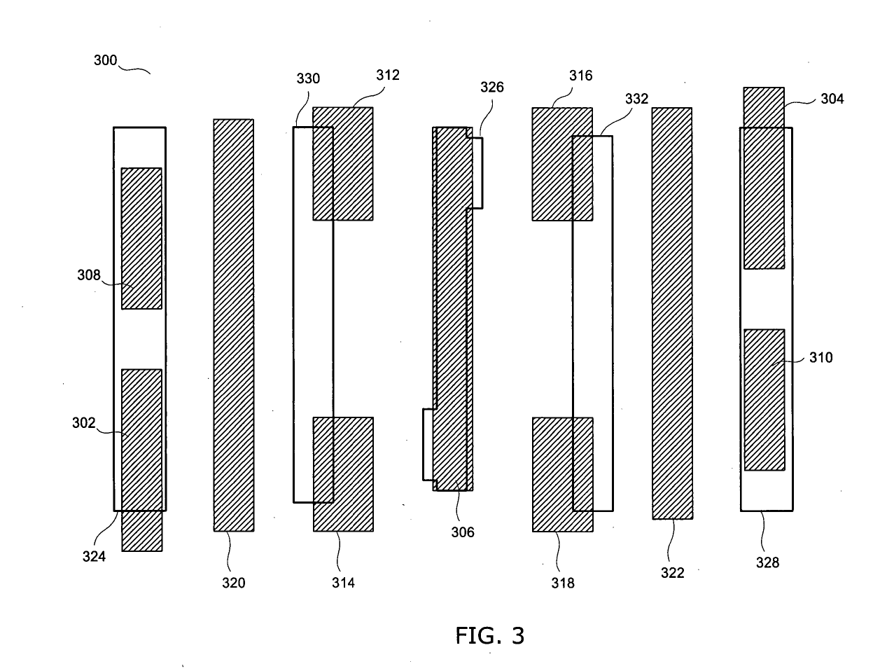

FIG. 3 illustrates a first layout 300 of the arrangement of second and fourth metal layers in accordance with a first embodiment of the present invention. The boxes representing the conductor lines with a pattern therein are placed on the second metal layer, and those empty boxes representing conductor lines placed on the fourth metal layer. These conductor lines are aligned parallel to the short side of the SRAM cell in order to minimize surface area, thereby minimizing the capacitance relative to the substrate. The second metal layer includes VSS landing pads 302 and 304, a VCC line 306, a port-1 word line landing pad 308, a port-2 word line landing pad 310, area 312 is the port-1 bit line bar landing pad, areas 314 and 316 are optional layers for VSS landing pads, and area 318 is a port-2 bit line landing pad, a port-1 bit line 320, and a port-2 bit line bar 322. The fourth metal layer includes VSS lines 324, 326 and 328, a port-1 bit line bar 330, and a port-2 bit line 332. As it is shown, for port-1, its bit line 320 is two metal layers below its bit line bar 330. Similarly, for port-2, its bit line bar 322 is also two metal layers below its bit line 332. This two-layer separation between the bit line and bit line bar reduces mutual capacitance, cross-talk, and noise. Further, there is one VSS conductor line or one VCC conductor line between port-1 bit line and port-2 bit line or between port-1 bit line bar and port-2 bit line bar for noise shielding.

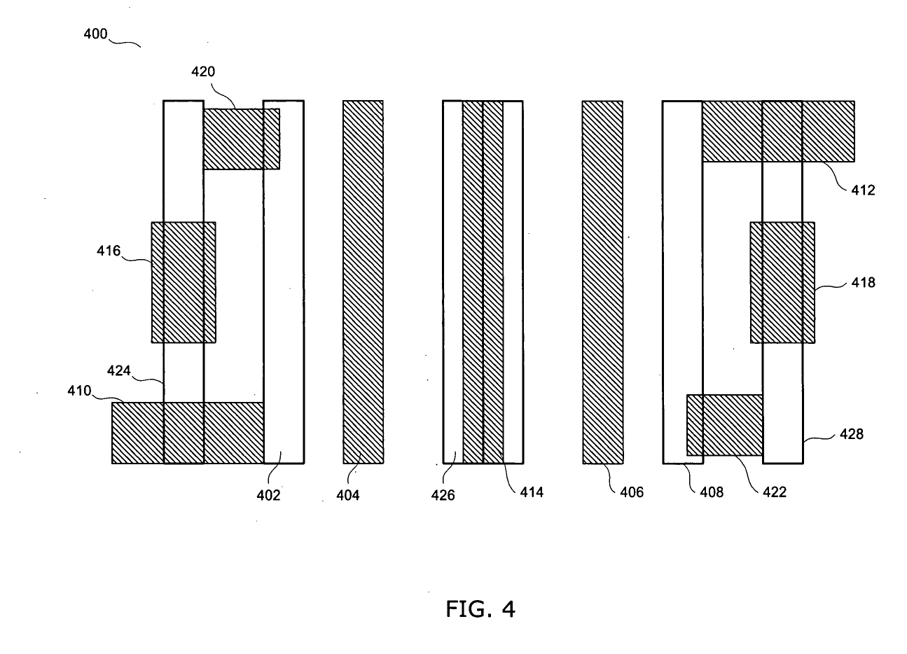

FIG. 4 illustrates a second layout 400 of the arrangement of the second and fourth metal layers, in accordance with a second embodiment of the present invention. The most significant difference between the layout 300, in FIG. 3, and the layout 400, in FIG. 4, is the reversal of metal layer choice between port-1 bit line and bit line bar conductor lines, and also between port-2 bit line and bit line bar conductor lines. The bit line and the bit line bar for any particular port are still separated on different metal layers and are parallel to the short side of the cell. The fourth metal layer includes a port-1 bit line 402. The second metal layer includes a port-1 bit line bar 404, a port-2 bit line 406, and a port-2 bit line bar 408. All the other metal layer assignments are the same as in the layout 300. As an embodiment, the second metal layer also includes VSS landing pads 410 and 412, a VCC line 414, a port-1 word line landing pad 416, a port-2 word line landing pad 418, and areas 420 and 422 which are landing pads for port-1 bit line 402 and port-2 bit line bar 408 respectively. The fourth metal layer also includes VSS lines 424, 426, and 428. All the same advantages of reduced capacitance, cross-talk, and noise and increased speed apply here as in the layout 300. As it is illustrated in FIGS. 3 and 4, the VCC or VSS line is placed between two bit signal lines on a metal layer.

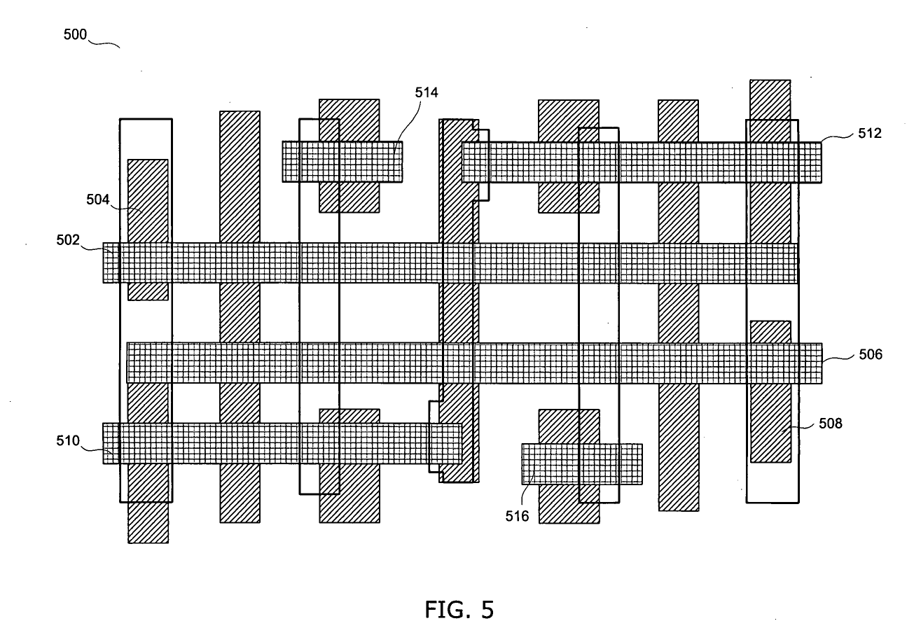

FIG. 5 presents a layout 500 illustrating the pattern of the conductor lines in the third metal layer, in accordance with one embodiment of the present invention. All the conductor lines in the third metal layer sit between the second and the fourth metal layers, and are aligned parallel to the long side of the SRAM cell, and perpendicular to the conductor lines of the second and fourth metal layers. The lines of the third metal layer are shown in the context of the layout 300 of the second and fourth metal layers. A port-1 word line 502 is connected to a port-1 word line landing pad 504 in the second metal layer. A port-2 word line 506 is connected to a port-2 word line landing pad 508 in the second metal layer. Areas 510 and 512 are VSS landing pads. Area 514 is a port-1 bit line bar landing pad. Area 516 is a port-2 bit line landing pad. As these lines of the third metal layer are woven between the conductor lines of the second and the fourth metal layers, they function as shielding to further reduce noise and cross-talk coupling between bit lines and also between bit lines bar. It is further noticed that the rectangular cell area, as shown in FIGS. 2-5, has relatively longer sides and relatively shorter sides. In some embodiment, it is preferred that the longer side is two or more times longer than the shorter side so that the aspect ratio of the cell area is more than two.

As technology advances, the gate length and gate oxide thickness continues to shrink for high-speed requirements. The above-described cell structure provides a memory device cell structure that has a significant performance improvement. The combination of a vertical separation of conductor lines for bit line and bit line bar, for each of two data ports, with the interposition of word line conductor lines between them, as shielding, produces significant improvements in speed, stability of memory data retention, and latch-up immunity, with minimum impact from leakage current, bit line loading, and bit line coupling effects. Furthermore, this improved cell structure has a shorter well path, thus having a lower well resistance between cell transistors and the well strap. This can restrict the parasitic bipolar transistor from turning on to cause latch-up.

The above invention provides many different embodiments, or embodiments for implementing different features of the invention. Specific embodiments of components, and processes are described to help clarify the invention. These are, of course, merely embodiments and are not intended to limit the invention from that described in the claims.

Although illustrative embodiments of the invention have been shown and described, other modifications, changes, and substitutions are intended in the foregoing invention. Accordingly, it is appropriate that the appended claims be construed broadly, and in a manner consistent with the scope of the invention, as set forth in the following claims.

1. A dual port static random access memory (SRAM) cell structure, the SRAM cell occupying a substantially rectangular cell area, the structure comprising:
a first port having two bit signal lines; and
a second port having two bit signal lines,
wherein the two bit signal lines of each port are on two separate metal layers.

2. The cell structure of claim 1 wherein the bit signal lines are parallel to a short side of the rectangular cell area.

3. The cell structure of claim 1 further comprising one or more semiconductor wells placed therein for forming one or more transistors thereon, the wells having the same orientation as the rectangular cell area.

4. The cell structure of claim 1 further comprising one or more power supply lines placed parallel to the short sides of the cell area.

5. The cell structure of claim 4 wherein at least one power supply line is placed between two bit signal lines on a metal layer.

6. The cell structure of claim 1 further comprising an additional metal layer having one or more word lines situated between the two metal layers having the bit signal lines.

7. The cell structure of claim 1 wherein a relatively longer side of the rectangular cell area is at least two times longer than a relatively shorter side thereof.

8. A dual port static random access memory (SRAM) cell structure, the SRAM cell occupying a substantially rectangular cell area, the structure comprising:
a first port having a first bit line and first bit line bar for its bit signal lines;
a second port having a second bit line and second bit line bar for its bit signal lines;
a first power supply line (VCC);
a second power supply line (VSS);
one or more word lines;
wherein the first bit line and the second bit line bar are on a first metal layer, the first bit line bar and the second bit line are on a second metal layer, and
wherein one or more wells for forming transistors thereon for the SRAM cell are in the same orientation as the rectangular cell area.

9. The cell structure of claim 8 wherein the bit signal lines are parallel to a short side of the rectangular cell area.

10. The cell structure of claim 8 wherein the power supply lines are placed parallel to the short sides of the cell area.

11. The cell structure of claim 10 wherein at least one power supply line is placed between two bit signal lines on a metal layer.

12. The cell structure of claim 10 wherein two bit signal lines on the same metal layer are separated by at least one non-bit signal line.

13. The cell structure of claim 8 further comprising a third metal layer having one or more word lines situated between the first and second metal layers.

14. The cell structure of claim 8 wherein a relatively longer side of the rectangular cell area is at least two times longer than a relatively shorter side thereof.

15. A dual port eight-transistor static random access memory (SRAM) cell structure, the SRAM cell occupying a substantially rectangular cell area, the structure comprising:
four nMOS pass gate transistors; and
two inverter modules each having pMOS and nMOS transistors, the transistors being formed on a plurality of material layers comprising:
a first metal layer providing one or more connection modules for connecting drain nodes of each inverter module to gates of the other inverter module;
a second metal layer providing a first bit signal line of a first port and a first bit signal line of a second port;
a third metal layer providing one or more word line signals;
a fourth metal layer providing a second bit signal line of the first port and a second bit signal line of the second port,
wherein the bit signal lines are placed parallel to short sides of the rectangular cell area, and
wherein the separation of the bit signal lines of the same port to two different metal layers and the separation of the second and fourth metal layers by the third metal layer reduce bit line coupling effect and noises.

16. The cell structure of claim 15 further comprising one or more wells for forming transistors thereon being in the same orientation as the rectangular cell area.

17. The cell structure of claim 15 further comprising a first power supply line (VCC) and a second power supply line (VSS) wherein at least one VCC or VSS is placed between the bit signal lines on a metal layer.

18. The cell structure of claim 17 wherein the VCC and VSS are placed parallel to the short sides of the cell area.

19. The cell structure of claim 15 wherein two bit signal lines on the same metal layer are separated by at least one non-bit signal line.

20. The cell structure of claim 15 wherein a relatively longer side of the rectangular cell area is at least two times longer than a relatively shorter side thereof.

21. A dual port eight-transistor static random access memory (SRAM) cell structure, the SRAM cell occupying a substantially rectangular cell area having an aspect ratio larger than two, the structure comprising:
four NMOS pass gate transistors; and
two inverter modules each having pMOS and nMOS transistors, the transistors being formed on a plurality of material layers comprising:
a first port having a first bit line and first bit line bar for its bit signal lines;
a second port having a second bit line and second bit line bar for its bit signal lines;
two or more contact structures for connecting to a negative power supply; and
one or more word lines.

22. The cell structure of claim 21 wherein the bit signal lines of the same port are placed on two different metal layers for reducing bit line coupling effect and noises.

23. The cell structure of claim 22 wherein the bit signal lines are parallel to a short side of the rectangular cell area.

24. The cell structure of claim 23 wherein the bit signal lines on a same metal layer are separated by at least one non-bit line signal.

25. The cell structure of claim 23 further comprising a metal layer for one or more word line conductors situated between two other metal layers carrying the bit lines and bit line bars.

26. The cell structure of claim 23 further comprising at least two or more via structures connecting to the negative power supply.

27. The cell structure of claim 26 further comprising two or more via structures for connecting to the word lines and their landing pads.
